(19) United States
(12) Patent Application Publication
(10) Pub. No.: US 2026/0135565 A1
(43) Pub. Date: May 14, 2026

(54) ANALOG-TO-DIGITAL CONVERSION DEVICE AND ANALOG-TO-DIGITAL CONVERSION METHOD

(71) Applicant: REALTEK SEMICONDUCTOR CORPORATION, HSINCHU (TW)

(72) Inventors: WEI-CIAN HONG, Hsinchu (TW); WEI-CHOU WANG, Hsinchu (TW)

(21) Appl. No.: 19/344,599

(22) Filed: Sep. 30, 2025

(30) Foreign Application Priority Data
Nov. 11, 2024 (TW) 113143268

(51) Int. Cl. H03M 1/44

(52) U.S. Cl. CPC H03M 1/442

(57) ABSTRACT

An analog-to-digital conversion device includes a switch, a capacitor array, a comparator, and a logical control circuit. The switch is configured to sample at least one input signal according to a sampling signal. The capacitor array includes a plurality of capacitors. The plurality of capacitors are configured to store the at least one input signal. The comparator is configured to generate a comparing result according to the at least one input signal stored in the plurality of capacitors of the capacitor array. The logical control circuit is configured to respectively reset the plurality of capacitors according to a conversion end signal or the sampling signal.

### BACKGROUND OF THE INVENTION

### 1. Field of the Invention

The present disclosure relates to an analog-to-digital conversion device and an analog-to-digital conversion method, especially to an analog-to-digital conversion device and an analog-to-digital conversion method for avoiding transient current spike.

### 2. Description of Related Art

Analog-to-digital converters (ADCs) are commonly used in electronic devices to convert analog signals into digital signals that can be processed by the electronic devices. A successive approximation register analog-to-digital converter (SAR ADC) is a commonly used type of ADC. The capacitor array of the SAR ADC can be configured to store an input signal, and then generate a digital signal through the collaborative operation of its comparator and logical control circuit.

After the conversion process is completed, the SAR ADC needs to reset the capacitor array for executing the next conversion. However, the reset operation of conventional SAR ADC is performed by simultaneously resetting a plurality of capacitors in the capacitor array, which may cause a transient current spike and affect the SAR ADC.

### SUMMARY OF THE INVENTION

In some aspects, an object of the present disclosure is to, but not limited to, provides an analog-to-digital conversion device and an analog-to-digital conversion method that makes an improvement to the prior art.

An embodiment of the analog-to-digital conversion device of the present disclosure includes a switch, a capacitor array, a comparator, and a logical control circuit. The switch is configured to sample at least one input signal according to a sampling signal. The capacitor array includes a plurality of capacitors. The plurality of capacitors are configured to store the at least one input signal. The comparator is configured to generate a comparing result according to the at least one input signal stored in the plurality of capacitors of the capacitor array. The logical control circuit is configured to respectively reset the plurality of capacitors according to a conversion end signal or the sampling signal.

An embodiment of the analog-to-digital conversion method of the non-volatile memory device of the present disclosure includes: sampling at least one input signal according to a sampling signal by a switch; storing the at least one input signal by a plurality of capacitors of a capacitor array; generating a comparison result according to the at least one input signal stored in the plurality of capacitors of the capacitor array by a comparator circuit; and respectively resetting the plurality of capacitors according to a conversion end signal or the sampling signal by a logical control circuit.

Technical features of some embodiments of the present disclosure make an improvement to the prior art. The analog-to-digital conversion device and the analog-to-digital conversion method of the present disclosure can respectively reset the plurality of capacitors of the capacitor array to avoid a transient current spike that may be caused by simultaneously resetting the plurality of capacitors.

These and other objectives of the present invention will no doubt become obvious to those of ordinary skill in the art after reading the following detailed description of the preferred embodiments that are illustrated in the various figures and drawings.

### BRIEF DESCRIPTION OF THE DRAWINGS

FIG. 1 shows an embodiment of an analog-to-digital conversion device of the present disclosure.

FIG. 2 shows an embodiment of a flow diagram of an analog-to-digital conversion method of the present disclosure.

FIG. 3 shows an embodiment of a timing diagram of an analog-to-digital conversion device of the present disclosure.

FIG. 4 shows an embodiment of a timing diagram of an analog-to-digital conversion device of the present disclosure.

FIG. 5 shows an embodiment of a timing diagram of an analog-to-digital conversion device of the present disclosure.

FIG. 6 shows an embodiment of a timing diagram of an analog-to-digital conversion device of the present disclosure.

FIG. 7 shows an embodiment of a timing diagram of an analog-to-digital conversion device of the present disclosure.

FIG. 8 shows an embodiment of a timing diagram of an analog-to-digital conversion device of the present disclosure.

FIG. 9 shows an embodiment of a timing diagram of an analog-to-digital conversion device of the present disclosure.

FIG. 10 shows an embodiment of a timing diagram of an analog-to-digital conversion device of the present disclosure.

FIG. 11 shows an embodiment of an analog-to-digital conversion device of the present disclosure.

FIG. 12 shows an embodiment of an asynchronous controller of the analog-to-digital conversion device shown in FIG. 11 of the present disclosure.

FIG. 13 shows an embodiment of a timing diagram of an asynchronous controller of the present disclosure.

### DETAILED DESCRIPTION OF THE PREFERRED EMBODIMENTS

To address the issue in the prior art where simultaneously resetting a plurality of capacitors of a capacitor array causes a transient current spike, the present disclosure provides an analog-to-digital conversion device and an analog-to-digital conversion method, which will be described in detail below.

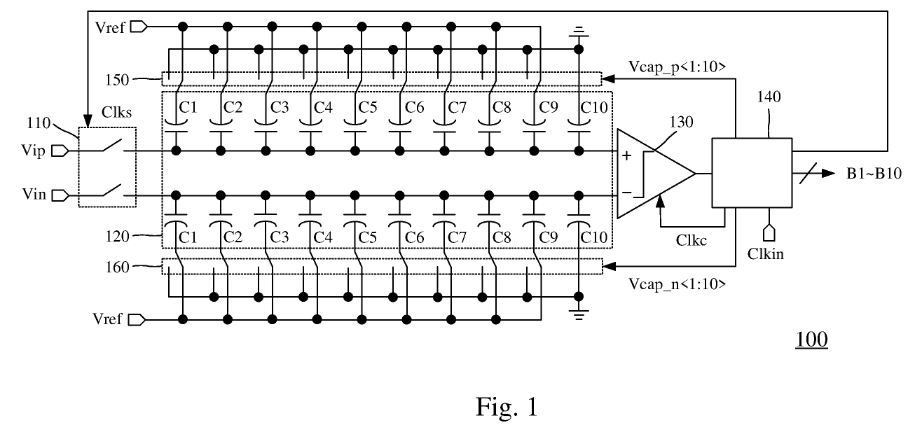

FIG. 1 shows an embodiment of an analog-to-digital conversion device 100 of the present disclosure. As shown in the figure, the analog-to-digital conversion device 100 includes a switch 110, a capacitor array 120, a comparator circuit 130, a logical control circuit 140, a switch 150, and a switch 160. The switch 110 is coupled to the capacitor array 120 and the logical control circuit 140. The capacitor array 120 is coupled to the comparator circuit 130. The comparator circuit 130 is coupled to the logical control circuit 140. The logical control circuit 140 is coupled to the switch 150 and the switch 160.

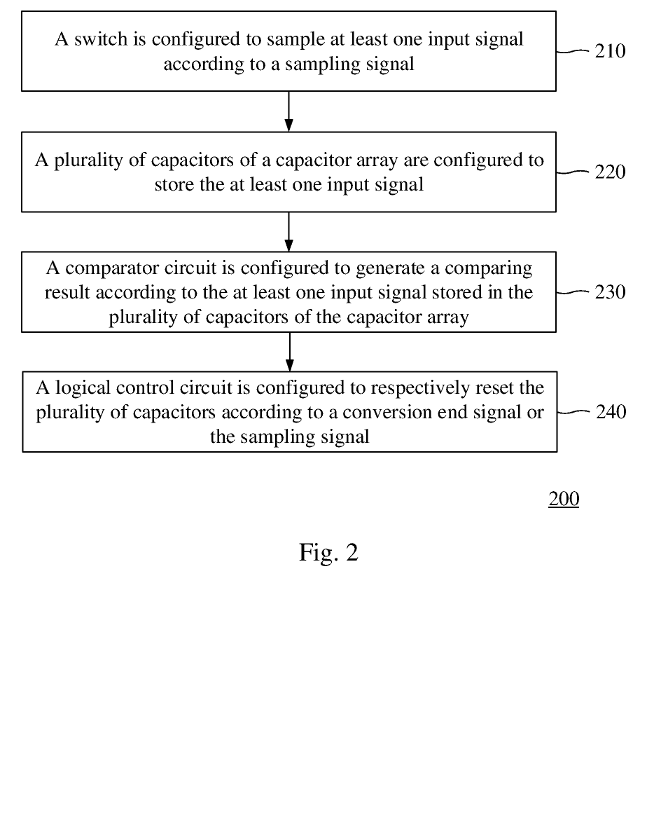

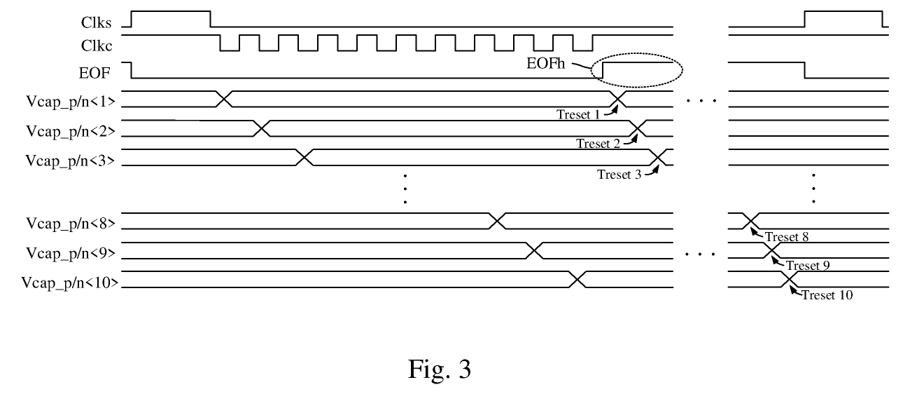

To facilitate understanding of the operation of the analog-to-digital conversion device 100, please refer to FIG. 2 and FIG. 3. FIG. 2 shows an embodiment of a flow diagram of an analog-to-digital conversion method 200 of the present disclosure. FIG. 3 shows an embodiment of a timing diagram of the analog-to-digital conversion device 100 of the present disclosure.

Referring to step 210 of FIG. 2, a switch is configured to sample at least one input signal according to a sampling signal. For example, referring to FIGS. 1 and 3, the switch 110 samples at least one input signal Vip, Vin according to a high-level sampling signal Clks.

Referring to step 220 of FIG. 2, a plurality of capacitors of a capacitor array are configured to store the at least one input signal. For example, referring to FIGS. 1 and 3, the plurality of capacitors C1~C10 of the capacitor array 120 store the at least one input signal Vip, Vin. In some embodiments, each capacitor label of the capacitors C1~C10 may include a pair of capacitors, and the capacitors are configured to store one bit of the input signals Vip, Vin. For example, the capacitor C1 may include a pair of capacitors, and the capacitors are configured to store one bit of the input signals Vip, Vin.

Referring to step 230 of FIG. 2, a comparator circuit is configured to generate a comparing result according to the at least one input signal stored in the plurality of capacitors of the capacitor array. For example, referring to FIGS. 1 and 3, the comparator circuit 130 compares the at least one input signal Vip, Vin stored in the plurality of capacitors C1~C10 of the capacitor array 120 according to an enable signal Clkc, thereby generating a comparing result. The comparing result is then transmitted to the logical control circuit 140. The logical control circuit 140 is configured to generate data B1~B10 according to the comparing result, and transmit the data B1~B10 to a digital signal processing device (not shown) for further signal processing.

Referring to step 240 of FIG. 2, a logical control circuit is configured to respectively reset the plurality of capacitors according to a conversion end signal or the sampling signal. For example, referring to FIGS. 1 and 3, the logical control circuit 140 respectively resets the plurality of capacitors C1~C10 according to a high-level conversion end signal EOFh. Specifically, the capacitor C1 of the capacitor array 120 stores one bit signal (e.g., signal Vcap_p/n<1>) of the at least one input signal Vip, Vin, the capacitor C2 stores another bit signal (e.g., signal Vcap_p/n<2>) of the at least one input signal Vip, Vin, and so on. Overall, the logical control circuit 140 resets the capacitor C1 at the reset time Treset1, resets the capacitor C2 at the reset time Treset2, and finally resets the capacitor C10 at the reset time Treset10, according to the high-level conversion end signal EOFh. It should be noted that the bit signal Vcap_p/n<1> stored in the capacitor C1 after being reset may be 0 or 1, depending on the design requirement of the analog-to-digital conversion device 100. Similarly, the bit signal Vcap_p/n<2> stored in the capacitor C2 after being reset may be 0 or 1, and so on.

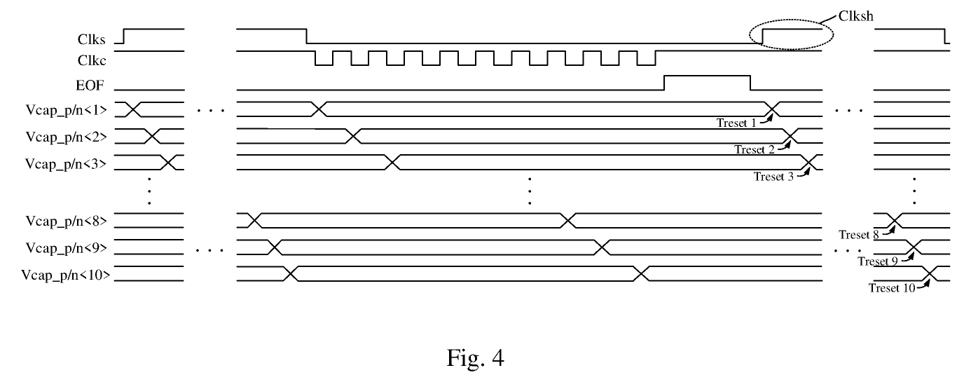

In another embodiment, referring to FIGS. 1 and 4, the logic control circuit 140 is configured to respectively reset the plurality of capacitors C1~C10 according to a high-level sampling signal Clksh. Specifically, the capacitor C1 of the capacitor array 120 stores one bit signal (e.g., bit signal Vcap_p/n<1>) of the at least one input signal Vip, Vin, the capacitor C2 stores another bit signal (e.g., bit signal Vcap_p/n<2>) of the at least one input signal Vip, Vin, and so on. Overall, the logic control circuit 140 resets the capacitor C1 at the reset time Treset1, the logic control circuit 140 resets the capacitor C2 at the reset time Treset2, and the logic control circuit 140 finally resets the capacitor C10 at the reset time Treset10 according to the high-level sampling signal Clksh.

It should be noted that in the embodiment shown in FIG. 4, the bit signal Vcap_p/n<1> stored in the capacitor C1 after being reset may be 0 or 1, depending on the design requirements of the analog-to-digital conversion device 100. Similarly, the bit signal Vcap_p/n<2> stored in the capacitor C2 after being reset may be 0 or 1, and so on. Furthermore, the sampling signal Clksh used by the logic control circuit 140 to respectively reset the plurality of capacitors C1~C10 may be the sampling signal Clksh of the next conversion cycle. For example, in step 210 of FIG. 2, the switch 110 samples the at least one input signal Vip, Vin according to the sampling signal Clks of the current conversion cycle. After the current conversion cycle ends and the next conversion cycle begins, the sampling signal Clksh of the next conversion cycle serves as the trigger signal for reset, and the logic control circuit 140 respectively resets the plurality of capacitors C1~C10 according to the sampling signal Clksh of the next conversion cycle.

As described in the embodiments of FIGS. 1-4, the analog-to-digital conversion device 100 and the analog-to-digital conversion method 200 of the present disclosure can respectively reset the plurality of capacitors C1~C10 in the capacitor array 120, thereby avoiding the transient current spike caused by simultaneously resetting the plurality of capacitors C1~C10.

In some embodiments, the logic control circuit 140 sequentially resets the plurality of capacitors C1~C10 according to a conversion end signal or a sampling signal. Referring to FIGS. 1 and 3, the logic control circuit 140 sequentially resets the plurality of capacitors C1~C10 at the reset times Treset1~Treset10 according to the high-level conversion end signal EOFh. Referring to FIGS. 1 and 4, the logic control circuit 140 sequentially resets the plurality of capacitors C1~C10 according to the high-level sampling signal Clksh at the reset times Treset1~Treset10.

In some embodiments, the logic control circuit 140 sequentially resets a first capacitor corresponding to the Most Significant Bit (MSB) of the plurality of capacitors C1~C10 to a second capacitor corresponding to the Least Significant Bit (LSB) of the plurality of capacitors C1~C10 according to the conversion end signal or the sampling signal. Referring to FIGS. 1 and 3, the logic control circuit 140 sequentially resets the capacitor C1 corresponding to the MSB of the plurality of capacitors C1~C10 to the capacitor C10 corresponding to the LSB of the plurality of capacitors C1~C10 according to the high-level conversion end signal EOFh. Specifically, the logic control circuit 140 resets the capacitor C1 corresponding to the MSB at the reset time Treset1, then the logic control circuit 140 resets the capacitor C2 at the reset time Treset2, and so on, until the logic control circuit 140 resets the capacitor C10 corresponding to the LSB at the reset time Treset10.

Referring to FIGS. 1 and 4, the logic control circuit 140 sequentially resets the capacitor C1 corresponding to the MSB of the plurality of capacitors C1~C10 to the capacitor C10 corresponding to the LSB of the plurality of capacitors C1~C10 according to the high-level sampling signal Clksh. Specifically, the logic control circuit 140 resets the capacitor C1 corresponding to the MSB at a the reset time Treset1, then the logical control circuit 140 resets the capacitor C2 at the reset time Treset2, and so on, until the logical control circuit 140 resets the capacitor C10 corresponding to the LSB at the reset time Treset10.

The analog-to-digital conversion device 100 of the present disclosure is not limited to the embodiments of FIGS. 3 and 4 for respectively resetting the capacitors C1~C10 of the capacitor array 120. The following sections will sequentially introduce other embodiments.

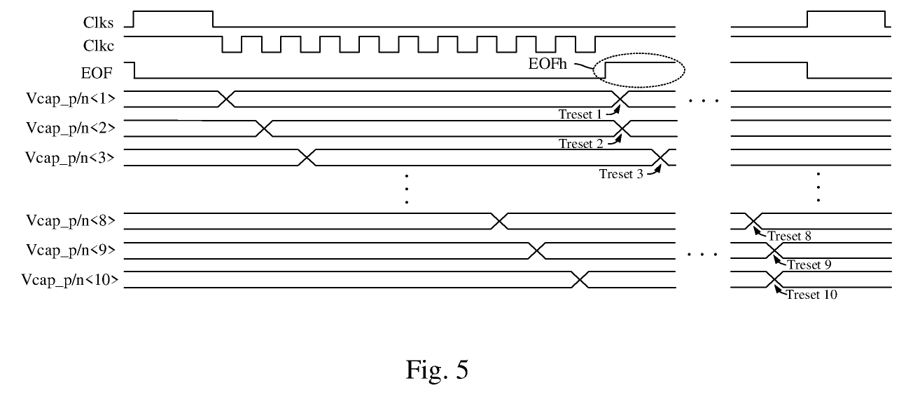

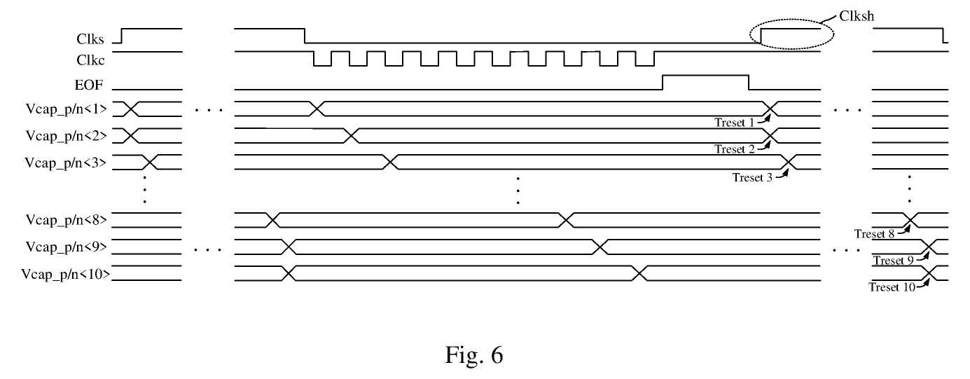

In some embodiments, the logic control circuit 140 simultaneously resets at least two capacitors of the plurality of capacitors C1~C10 according to the conversion end signal or the sampling signal. The at least two capacitors respectively correspond to different bits of the at least one input signal Vip, Vin. For example, referring to FIGS. 1 and 5, the logic control circuit 140 resets the capacitors C1 and C2 of the capacitors C1~C10 at the same reset times Treset1, Treset2 according to the high-level conversion end signal EOFh, and the capacitor C1 and the capacitor C2 in the previous embodiments respectively correspond to different bits of the at least one input signal Vip, Vin. In another embodiment, referring to FIGS. 1 and 6, the logic control circuit 140 resets the capacitors C1 and C2 of the plurality of capacitors C1~C10 at the same reset times Treset1, Treset2 according to the high-level sampling signal Clksh, and the capacitor C1 and the capacitor C2 in previous embodiments respectively correspond to different bits of the at least one input signal Vip, Vin.

In some embodiments, the logic control circuit 140 resets a first capacitor and a second capacitor of the plurality of capacitors C1~C10 at a first reset time, and resets a third capacitor and a fourth capacitor of the plurality of capacitors C1~C10 at a second reset time according to a conversion end signal or a sampling signal. For example, referring to FIGS. 1 and 5, the logic control circuit 140, according to the high-level conversion end signal EOFh, resets the capacitor C1 and the capacitor C2 of the plurality of capacitors C1~C10 at the same reset times Treset1, Treset2, resets the capacitor C3 and the capacitor C4 of the plurality of capacitors C1~C10 at the same reset times Treset3, Treset4, and so on. Ultimately, the logic control circuit 140 resets the capacitor C9 and the capacitor C10 of the plurality of capacitors C1~C10 at the same reset times Treset9, Treset10. Referring to FIGS. 1 and 6, the logic control circuit 140, according to the high-level sampling signal Clksh, resets the capacitor C1 and the capacitor C2 of the plurality of capacitors C1~C10 at the same reset times Treset1, Treset2, resets the capacitor C3 and the capacitor C4 of the plurality of capacitors C1~C10 at the same reset times Treset3, Treset4, and so on. Ultimately, the logic control circuit 140 resets the capacitor C9 and the capacitor C10 of the plurality of capacitors C1~C10 at the same reset times Treset9, Treset10.

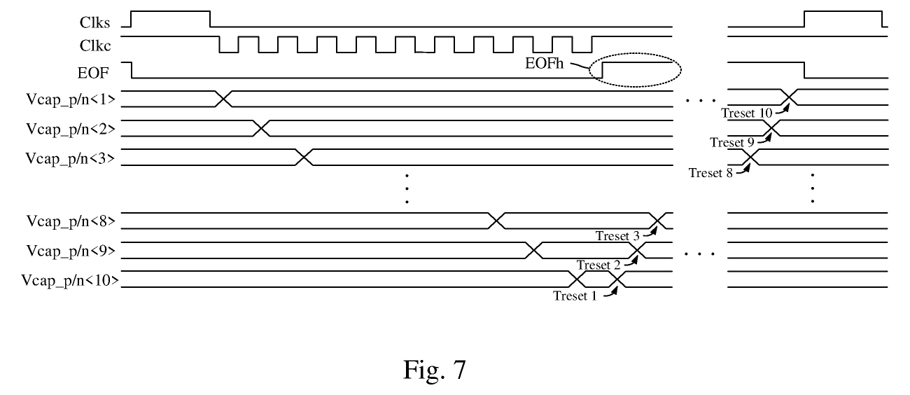

In some embodiments, the logic control circuit 140 sequentially resets a first capacitor corresponding to the Least Significant Bit (LSB) of the plurality of capacitors C1~C10 to a second capacitor corresponding to the Most Significant Bit (MSB) of the plurality of capacitors C1~C10 according to a conversion end signal or a sampling signal. For example, referring to FIGS. 1 and 7, the logic control circuit 140, according to the high-level conversion end signal EOFh, sequentially resets the capacitor C10 corresponding to the LSB of the plurality of capacitors C1~C10 to the capacitor C1 corresponding to the MSB of the plurality of capacitors C1~C10. In detail, the logic control circuit 140, according to the high-level conversion end signal EOFh, resets the capacitor C10 corresponding to the LSB at the reset time Treset1, then the logical control circuit 140 resets the capacitor C9 at the reset time Treset2, and so on. Ultimately, the logic control circuit 140 resets the capacitor C1 corresponding to the MSB at the reset time Treset10.

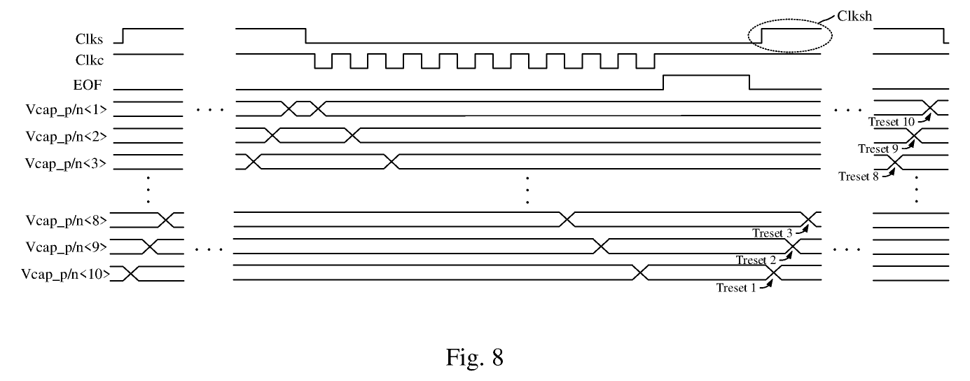

Referring to FIGS. 1, 8, the logic control circuit 140, according to the high-level sampling signal Clksh, sequentially resets the capacitor C10 corresponding to the LSB of the plurality of capacitors C1~C10 to the capacitor C1 corresponding to the MSB of the plurality of capacitors C1~C10. In detail, the logic control circuit 140, according to the high-level sampling signal Clksh, resets the capacitor C10 corresponding to the LSB at the reset time Treset1, then the logic control circuit 140 resets the capacitor C9 at the reset time Treset2, and so on. Ultimately, the logic control circuit 140 resets the capacitor C1 corresponding to the MSB at the reset time Treset10.

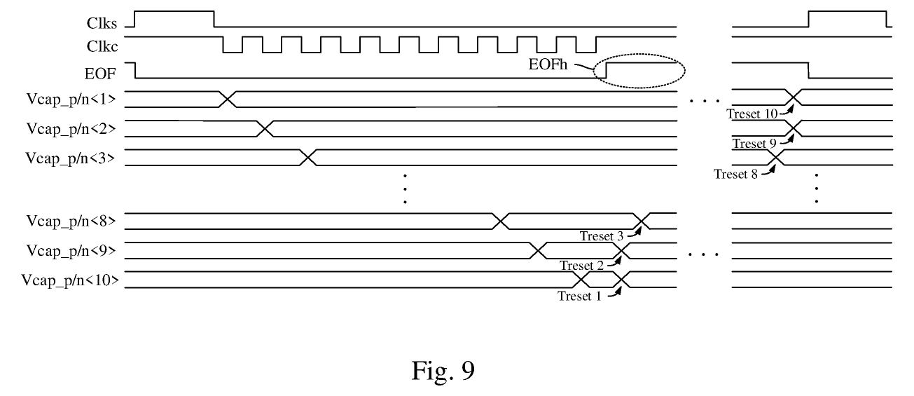

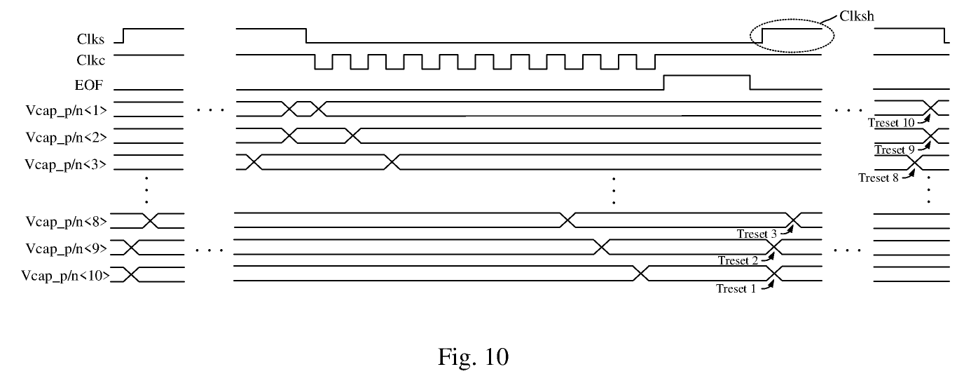

In some embodiments, the logic control circuit 140 simultaneously resets at least two capacitors of the plurality of capacitors C1~C10 according to a conversion end signal or a sampling signal. The at least two capacitors respectively correspond to different bits. For example, referring to FIGS. 1 and 9, the logic control circuit 140, according to the high-level conversion end signal EOFh, resets the capacitor C9 and the capacitor C10 of the plurality of capacitors C1~C10 at the same reset times Treset1, Treset2, and the capacitor C9 and the capacitor C10 in previous embodiment respectively correspond to different bits of the at least one input signal Vip, Vin. In another embodiment, referring to FIGS. 1 and 10, the logic control circuit 140, according to the high-level sampling signal Clksh, resets the capacitor C9 and the capacitor C10 of the plurality of capacitors C1~C10 at the same reset times Treset1, Treset2, and the capacitor C9 and the capacitorC10 in previous embodiment respectively correspond to different bits of the at least one input signal Vip, Vin.

It should be noted that the manner of resetting the plurality of capacitors C1~C10 in the analog-to-digital conversion device 100 of the present disclosure is not limited to the embodiments illustrated in FIG. 3~FIG. 10. In other embodiments, the analog-to-digital conversion device 100 of the present disclosure may simultaneously reset three capacitors, or the analog-to-digital conversion device 100 of the present disclosure may simultaneously reset more than three capacitors. In another embodiment, the analog-to-digital conversion device 100 of the present disclosure may simultaneously reset two non-adjacent capacitors (for example, simultaneously resetting the capacitors C1, C3), or the analog-to-digital conversion device 100 of the present disclosure may simultaneously reset three non-adjacent capacitors (for example, simultaneously resetting the capacitors C1, C3, C6). Furthermore, the analog-to-digital conversion device 100 of the present disclosure may simultaneously reset more than three non-adjacent capacitors. The manner of resetting the plurality of capacitors C1~C10 in the analog-to-digital conversion device 100 of the present disclosure can be determined according to actual requirements if the manner is a way of respectively resetting the plurality of capacitors C1~C10. In other words, if it is not a manner that simultaneously resets all of the capacitors C1~C10, it falls within the concept to be protected by the analog-to-digital conversion device 100 of the present disclosure.

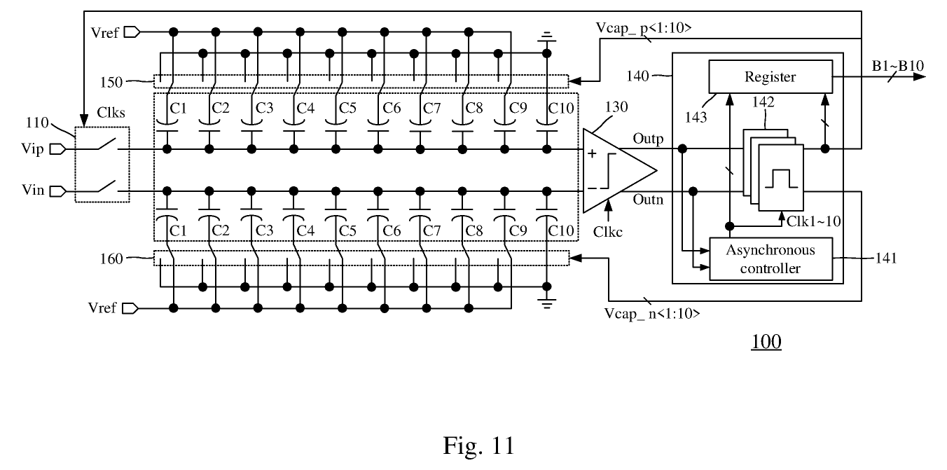

FIG. 11 shows an embodiment of an analog-to-digital conversion device 100 of the present disclosure. Compared with FIG. 1, the analog-to-digital conversion device 100 shown in FIG. 11 further illustrates the internal components of the logic control circuit 140.

As shown in the figure, the logic control circuit 140 includes an asynchronous controller 141, a latch 142, and a register 143. The asynchronous controller 141 is configured to output a plurality of clock signals Clk1~Clk10, and at least two of the plurality of clock signals Clk1~Clk10 are asynchronous. The latch 142 is configured to respectively reset a plurality of capacitors C1~C10 via switches 150, 160 according to the plurality of clock signals Clk1~Clk10. In addition, the latch 142 can store a comparing result from the comparator circuit 130. The register 143 reads the comparing result stored by the latch 142, and outputs data B1~B10 to a digital signal processing device (not shown) according to the comparing result for subsequent signal processing.

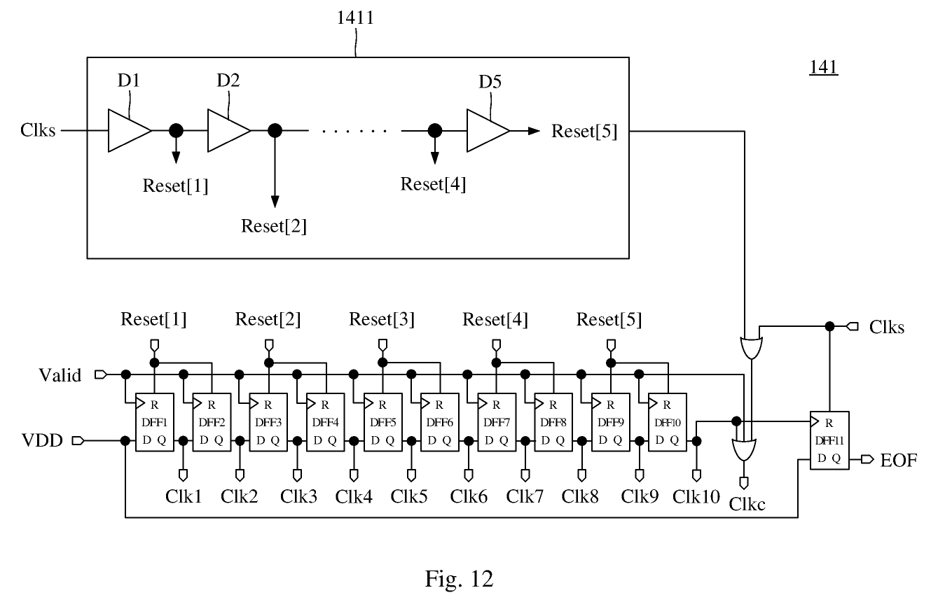

FIG. 12 shows an embodiment of an asynchronous controller 141 of the analog-to-digital conversion device 100 shown in FIG. 11 of the present disclosure. As shown in the figure, the asynchronous controller 141 includes a delay line 1411 and a plurality of flip-flops DFF1~DFF11.

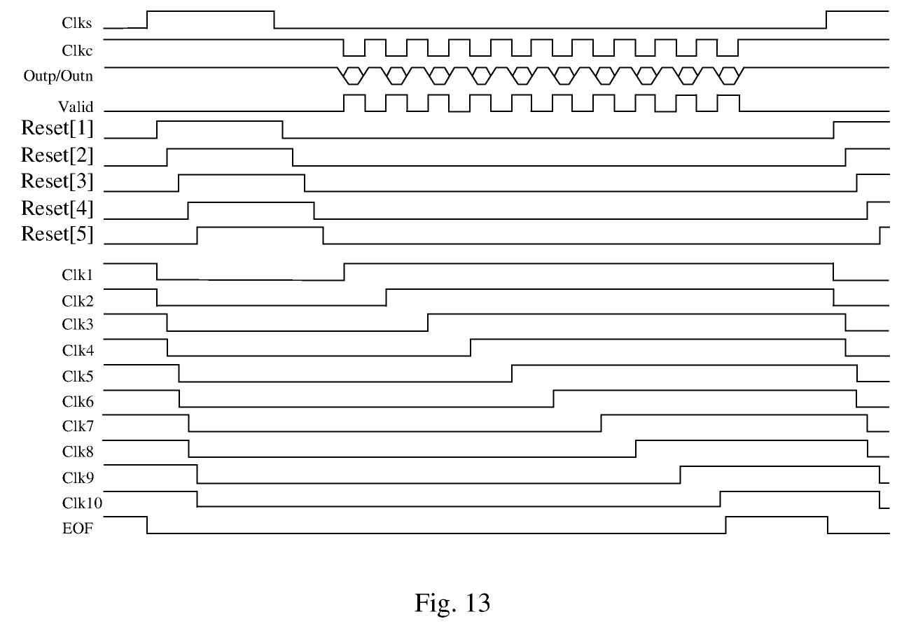

To facilitate understanding of the operation of the asynchronous controller 141 in FIG. 12, please also refer to FIG. 13, which illustrates a timing diagram of the asynchronous controller 141. The delay line 1411 is configured to delay a sampling signal Clks so as to generate a plurality of reset signals Reset[1]~Reset[5]. The plurality of flip-flops DFF1~DFF10 are configured to, according to the plurality of reset signals Reset[1]~Reset[5], generate a plurality of clock signals Clk1~Clk10, and transmit the plurality of clock signals Clk1~Clk10 to the latch 142 shown in FIG. 11. Subsequently, the latch 142 is configured to, according to the plurality of clock signals Clk1~Clk10, respectively reset the plurality of capacitors C1~C10. As described above, after the sampling signal Clks is delayed by the delay line 1411, the plurality of reset signals Reset[1]~Reset[5] having time differences as illustrated in FIG. 13 are generated. The flip-flops DFF1~DFF10 are then configured to, according to the reset signals Reset[1]~Reset[5] having time differences, generate the plurality of clock signals Clk1~Clk10 having time differences as shown in FIG. 13. Therefore, the latch 142 can, according to the clock signals Clk1~Clk10 having time differences, respectively reset the plurality of capacitors C1~C10.

In some embodiments, the delay line 1411 of FIG. 12 includes delay circuits D1~D5. The delay circuit D1 is configured to delay the sampling signal Clks so as to generate the reset signal Reset[1]. The delay circuit D2 is configured to delay the reset signal Reset[1] so as to generate the reset signal Reset[2], and so on. Finally, the delay circuit D5 is configured to delay the reset signal Reset[4] so as to generate the reset signal Reset[5]. In summary, the delay line 1411 of FIG. 12 is indeed capable of generating the plurality of reset signals Reset[1]~Reset[5] having time differences as illustrated in FIG. 13.

It should be noted that the present disclosure is not limited to the embodiments as shown in FIG. 1 to FIG. 13, they are merely examples for illustrating the implements of the present disclosure, and the scope of the present disclosure shall be defined based on the claims as shown below. In view of the foregoing, it is intended that the present disclosure covers modifications and variations to the embodiments of the present disclosure, and modifications and variations to the embodiments of the present disclosure also fall within the scope of the following claims and their equivalents.

As described above, technical features of some embodiments of the present disclosure make an improvement to the prior art. The analog-to-digital conversion device and the analog-to-digital conversion method of the present disclosure can respectively reset the plurality of capacitors of the capacitor array to avoid the transient current spike that may be caused by simultaneously resetting the plurality of capacitors.

It should be noted that people having ordinary skill in the art can selectively use some or all of the features of any embodiment in this specification or selectively use some or all of the features of multiple embodiments in this specification to implement the present invention as long as such implementation is practicable; in other words, the way to implement the present invention can be flexible based on the present disclosure.

The descriptions represent merely the preferred embodiments of the present invention, without any intention to limit the scope of the present invention thereto. Various equivalent changes, alterations, or modifications based on the claims of the present invention are all consequently viewed as being embraced by the scope of the present invention.

What is claimed is:

1. An analog-to-digital conversion device, comprising:
a switch, configured to sample at least one input signal according to a sampling signal;
a capacitor array, comprising a plurality of capacitors, wherein the plurality of capacitors are configured to store the at least one input signal;
a comparator circuit, configured to generate a comparing result according to the at least one input signal stored in the plurality of capacitors of the capacitor array; and
a logical control circuit, configured to respectively reset the plurality of capacitors according to a conversion end signal or the sampling signal.

2. The analog-to-digital conversion device of claim 1, wherein the logical control circuit sequentially resets the plurality of capacitors according to the conversion end signal or the sampling signal.

3. The analog-to-digital conversion device of claim 1, wherein the logic control circuit is configured to sequentially reset a first capacitor corresponding to a Most Significant Bit (MSB) of the plurality of capacitors to a second capacitor corresponding to a Least Significant Bit (LSB) of the plurality of capacitors according to the conversion end signal or the sampling signal.

4. The analog-to-digital conversion device of claim 1, wherein the logical control circuit simultaneously resets at least two capacitors of the plurality of capacitors according to the conversion end signal or the sampling signal, wherein the at least two capacitors respectively correspond to different bits of the at least one input signal.

5. The analog-to-digital conversion device of claim 1, wherein the logical control circuit resets a first capacitor and a second capacitor of the plurality of capacitors at a first reset time, and resets a third capacitor and a fourth capacitor of the plurality of capacitors at a second reset time according to the conversion end signal or the sampling signal.

6. The analog-to-digital conversion device of claim 1, wherein the logic control circuit sequentially resets a first capacitor corresponding to a Least Significant Bit (LSB) of the plurality of capacitors to a second capacitor corresponding to a Most Significant Bit (MSB) of the plurality of capacitors according to the conversion end signal or the sampling signal.

7. The analog-to-digital conversion device of claim 1, wherein the logical control circuit comprises:
an asynchronous controller, configured to output a plurality of clock signals, wherein at least two clock signals of the plurality of clock signals are asynchronous; and
a latch, respectively resets the plurality of capacitors according to the plurality of clock signals.

8. The analog-to-digital conversion device of claim 7, wherein the asynchronous controller comprises:
a delay line, configured to delay the sampling signal to generate a plurality of reset signals; and
a plurality of flip-flops, configured to generate the plurality of clock signals according to the plurality of reset signals, and transmit the plurality of clock signals to the latch.

9. The analog-to-digital conversion device of claim 8, wherein the delay line comprises:
a first delay circuit, configured to delay the sampling signal to generate a first reset signal of the plurality of reset signals; and
a second delay circuit, configured to delay the first reset signal to generate a second reset signal of the plurality of reset signals.

10. The analog-to-digital conversion device of claim 8, wherein a first reset signal of the plurality of reset signals and a second reset signal of the plurality of reset signals have a time difference.

11. An analog-to-digital conversion method, comprising:
sampling at least one input signal according to a sampling signal by a switch;
storing the at least one input signal by a plurality of capacitors of a capacitor array;
generating a comparison result according to the at least one input signal stored in the plurality of capacitors of the capacitor array by a comparator circuit; and
respectively resetting the plurality of capacitors according to a conversion end signal or the sampling signal by a logical control circuit.

12. The analog-to-digital conversion method of claim 11, wherein respectively resetting the plurality of capacitors according to the conversion end signal or the sampling signal by the logical control circuit comprises:
sequentially resetting the plurality of capacitors according to the conversion end signal or the sampling signal by the logical control circuit.

13. The analog-to-digital conversion method of claim 11, wherein respectively resetting the plurality of capacitors according to the conversion end signal or the sampling signal by the logical control circuit comprises:
sequentially resetting a first capacitor corresponding to a Most Significant Bit (MSB) of the plurality of capacitors to a second capacitor corresponding to a Least Significant Bit (LSB) of the plurality of capacitors according to the conversion end signal or the sampling signal by the logical control circuit.

14. The analog-to-digital conversion method of claim 11, wherein respectively resetting the plurality of capacitors according to the conversion end signal or the sampling signal by the logical control circuit comprises:
simultaneously resetting at least two capacitors of the plurality of capacitors according to the conversion end signal or the sampling signal by the logical control circuit, wherein the at least two capacitors respectively correspond to different bits of the at least one input signal.

15. The analog-to-digital conversion method of claim 11, wherein respectively resetting the plurality of capacitors according to the conversion end signal or the sampling signal by the logical control circuit comprises:
resetting a first capacitor and a second capacitor of the plurality of capacitors at a first reset time, and resetting a third capacitor and a fourth capacitor of the plurality of capacitors at a second reset time according to the conversion end signal or the sampling signal by the logical control circuit.

16. The analog-to-digital conversion method of claim 11, wherein respectively resetting the plurality of capacitors according to the conversion end signal or the sampling signal by the logical control circuit comprises:
sequentially resetting a first capacitor corresponding to a Least Significant Bit (LSB) of the plurality of capacitors to a second capacitor corresponding to a Most Significant Bit (MSB) of the plurality of capacitors according to the conversion end signal or the sampling signal by the logic control circuit.

17. The analog-to-digital conversion method of claim 11, wherein respectively resetting the plurality of capacitors according to the conversion end signal or the sampling signal by the logical control circuit comprises:
outputting a plurality of clock signals by an asynchronous controller of the logical control circuit, wherein at least two clock signals of the plurality of clock signals are asynchronous; and
respectively resetting the plurality of capacitors according to the plurality of clock signals by a latch of the logical control circuit.

18. The analog-to-digital conversion method of claim 17, wherein outputting the plurality of clock signals by the asynchronous controller of the logical control circuit comprises:
delaying the sampling signal to generate a plurality of reset signals by a delay line of the asynchronous controller; and
generating the plurality of clock signals according to the plurality of reset signals, and transmitting the plurality of clock signals to the latch by a plurality of flip-flops of the asynchronous controller.

19. The analog-to-digital conversion method of claim 18, wherein delaying the sampling signal to generate the plurality of reset signals by the delay line of the asynchronous controller comprises:
delaying the sampling signal to generate a first reset signal of the plurality of reset signals by a first delay circuit of the delay line; and
delaying the first reset signal to generate a second reset signal of the plurality of reset signals by a second delay circuit of the delay line.

20. The analog-to-digital conversion method of claim 18, wherein a first reset signal of the plurality of reset signals and a second reset signal of the plurality of reset signals have a time difference.
